(19) United States
(12) Patent Application Publication
(10) Pub. No.: US 2026/0168097 A1
(43) Pub. Date: Jun. 18, 2026

(54) EXTERNAL PART COMPRISING A STACK OF PROTECTIVE INTERFERENCE LAYERS

(71) Applicant: The Swatch Group Research and Development Ltd, Marin (CH)

(72) Inventors: Camille HALLER, Yverdon-les-Bains (CH); Loïc Curchod, Lausanne (CH); Mina Moradi, Olten (CH); Marie Baudoz, Morteau (FR); Giovanni Poly, Maiche (FR)

(73) Assignee: The Swatch Group Research and Development Ltd, Marin (CH)

(21) Appl. No.: 19/388,161

(22) Filed: Nov. 13, 2025

(30) Foreign Application Priority Data
Dec. 16, 2024 (EP) 24220332.1

(51) Int. Cl. C23C 16/455; C23C 16/06

(52) U.S. Cl. CPC C23C 16/45555; C23C 16/06

(57) ABSTRACT

An external part (10) for use in horology, jewellery or fine jewellery, including a substrate (100) having a metallic face (101) made of a noble metal or of a noble metal alloy in which the complex refractive index at a wavelength of 550 nm has a real part n<1 and an imaginary part 2<k<3, on which is deposited a stack of thin-film dielectric coatings (110), each consisting of a thin atomic film, formed by at least one alternation of layers made of TiO₂ and Al₂O₃ and comprising a terminal layer (111) made of TiO₂ and a base layer (112) resting on the metallic face (101) made of TiO₂ or of Al₂O₃.

### CROSS REFERENCE TO RELATED APPLICATIONS

This application claims priority to European Patent Application No. 24220332.1 filed Dec. 16, 2024, the entire contents of which are incorporated herein by reference.

### TECHNICAL FIELD OF THE INVENTION

The invention relates to the field of horology, jewellery or fine jewellery, and more specifically to an external part for use in horology, jewellery or fine jewellery.

In this specification, the term “external part” refers, as is commonly understood in the aforementioned fields, to a component that is visible to a user and has a decorative function, meaning that it contributes to the visual appearance of an object.

### TECHNOLOGICAL BACKGROUND

In the fields of horology, jewellery and fine jewellery, aesthetics is generally a major objective.

In the horology field, for example, external parts, such as dials, enable a horology brand to stand out from its competitors, help shape a brand's identity and attract potential customers.

Dials contain a substrate, generally made of a metallic material, for example brass, or noble metals such as gold or silver. These metallic materials are prone to corrosion and/or tarnishing, especially if they are applied in layers. To protect the substrate from any chemical damage, it is generally covered with a protective layer such as a varnish, for example Zapon. The protective layer is around several micrometres thick, for example more than 10 micrometres, so that it is sufficiently water-resistant to provide effective protection.

At such a thickness, the protective layer detracts from the visual appearance of any structuring of the substrate or its colour. This is particularly true if the substrate has structuring, as the thickness of the protective layer needs to be increased further to be effective.

### SUMMARY OF THE INVENTION

The invention remedies the aforementioned drawbacks and relates, to this end, to an external part for use in horology, jewellery or fine jewellery, comprising a substrate having a metallic face made of a noble metal or of a noble metal alloy, in solid form or as a thin film deposited on said substrate, for example by PVD or galvanic deposition, in which the complex refractive index at a wavelength of 550 nm has a real part n<1 and an imaginary part 2<k<3, on which is deposited a stack of thin-film dielectric coatings.

Each of the layers in the stack of thin-film dielectric coatings is comprised of a layer deposited by an ALD deposition method, and the stack is formed by at least one alternation of layers made of TiO₂ and Al₂O₃ and comprises a terminal layer made of TiO₂ and a base layer resting on the metallic face of the substrate made of TiO₂ or of Al₂O₃.

The invention advantageously makes it possible to guarantee the chemical and mechanical protection of the external part, while imparting a bright, precise colour thereto.

In particular embodiments, the invention can further comprise one or more of the following features, taken separately or in any technically possible combination.

In particular embodiments, the metallic face of the substrate is made of platinum or a platinum alloy.

In particular embodiments, the metallic face of the substrate is made of a gold alloy comprising 75% by mass of gold, and 25% by mass of silver and/or of copper to arrive at 100%.

In particular embodiments, the stack of thin-film dielectric coatings comprises two layers, the base layer being made of Al₂O₃.

In particular embodiments, the base layer has a thickness comprised between 1 nm and 10 nm, or even between 2 nm and 8 nm, and the terminal layer has a thickness comprised between 10 nm and 30 nm, or even between 15 nm and 25 nm.

In particular embodiments, the metallic face of the substrate is made of a gold alloy comprising 75% by mass of gold, from 4.5% to 5.5% by mass of silver and from 19.5% to 20.5% by mass of copper, the total being equal to 100%.

In particular embodiments, the stack of thin-film dielectric coatings comprises three layers, including an intermediate layer made of Al₂O₃ sandwiched between the base layer and the terminal layer, which are themselves made of TiO₂.

In particular embodiments, the base layer and the terminal layer have a thickness comprised between 35 nm and 55 nm, or even between 40 nm and 50 nm, and the intermediate layer has a thickness comprised between 50 nm and 70 nm, or even between 55 nm and 65 nm.

In particular embodiments, the metallic face of the substrate is made of a gold alloy comprising 75% by mass of gold, 15% to 16% by mass of silver and 9% to 10% by mass of copper, the total being equal to 100%.

### BRIEF DESCRIPTION OF THE FIGURES

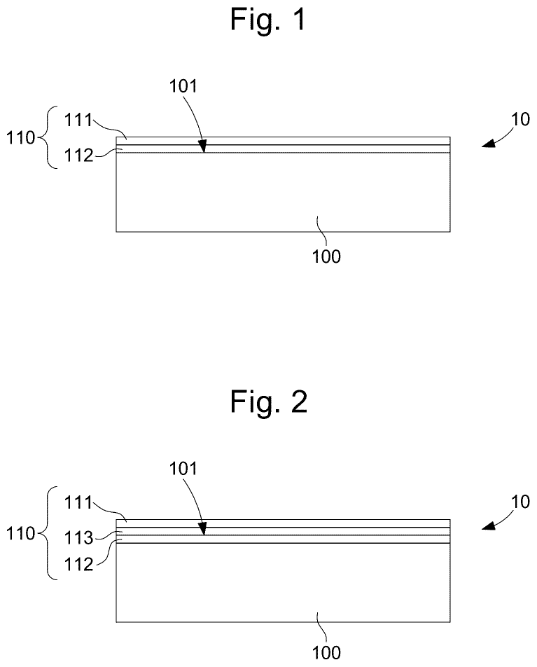

Other characteristics and advantages of the invention will become apparent from the following detailed description, which is given by way of non-limiting example, with reference to FIGS. 1 and 2 which schematically show a cross-sectional view of an external part according to two preferred embodiments of the present invention.

It should be noted that the figures are not drawn to scale for clarity reasons.

### DETAILED DESCRIPTION OF THE INVENTION

The present invention relates to an external part 10 for use in horology, jewellery or fine jewellery comprising a substrate 100 having a metallic face 101 made of a noble metal or of a noble metal alloy, that is, of an alloy comprising at least 30% by mass of noble metal.

The external part 10 according to the invention is schematically shown in FIGS. 1 and 2 and is particularly suitable for forming a dial for a timepiece, or any other preferentially internal part of the timepiece.

On its metallic face 101, the external part 10 comprises a stack of thin-film dielectric coatings 110 that are semi-transparent, that is, at least transparent in the visible range, each deposited by an atomic thin-film deposition method known to the person skilled in the art by the acronym “ALD” for “Atomic Layer Deposition.” Each layer in the thin-film dielectric coating 110 has a thickness comprised between a few nanometres and a few tens of nanometres. This characteristic makes it possible to protect the metallic face 101 of the external part 10 from chemical aggressions and to colour it by a precisely chosen interference effect in a repeatable and robust way. The thickness of the thin-film dielectric coating 110 is therefore homogeneous and consistent across its entire surface.

The metallic face 101 can have structuring, for example by mechanical machining, for example by manual engraving or machining with a numerically controlled machine tool, by chemical machining or by laser machining. The structuring is formed by hollows and peaks, the distance between the hollows and peaks being, for example, at least 1 μm.

The stack of thin-film dielectric coatings 110 is formed by at least one alternation of layers made of TiO₂ and Al₂O₃ and comprises a terminal layer 111 made of TiO₂ and a base layer 112 resting on the metallic face 101 made of TiO₂ or of Al₂O₃.

It is be understood in this case that the nature of the base layer 112 depends on the number of thin-film dielectric coatings 110, and in particular on whether the number of thin-film dielectric coatings is even or odd.

The interference colour obtained by the combination of the stack of thin-film dielectric coatings 110 and the metallic face 101 depends in particular on the thickness of each thin-film dielectric coating 110, on their arrangement and their number, and the material of which the metallic face 101 is made.

In particular, the present invention proposes a specific arrangement of the stack of thin-film dielectric coatings 110 associated with a metallic face 101 made of a noble metal or of a noble metal alloy in which the complex refractive index at a wavelength of 550 nm has a real part n<1 and an imaginary part 2<k<3.

Advantageously, due to the choice of the nature and thickness of the layers of the stack of thin-film dielectric coatings 110 and the material of the support face 101, the interference colour generated by the characteristics of the invention is very precise.

In a particular example of the present invention, the metallic face 101 is made of gold or platinum, or an alloy of one of these metals and can comprise iridium, palladium, platinum, rhodium, etc.

In particular, in the embodiment schematically shown in FIG. 1, the stack of thin-film dielectric coatings 110 comprises two layers, including a base layer 112 made of Al₂O₃.

The base layer 112 has a thickness comprised between 1 nm and 10 nm, or even between 2 nm and 8 nm, and the terminal layer 111 has a thickness comprised between 10 nm and 30 nm, or even between 15 nm and 25 nm.

In this exemplary embodiment, the metallic face 101 is made of a gold alloy, for example comprising 75% by mass of gold, and 25% by mass of silver and/or of copper to arrive at 100%, for example a gold alloy comprising 75% by mass of gold, from 4.5% to 5.5% by mass of silver and from 19.5% to 20.5% by mass of copper.

The metallic face 101 thus has a complex refractive index at a wavelength of 550 nm, in which the real part n is equal to 0.7 and in which the imaginary part k is equal to 2.5.

The interference colour obtained using the parameters mentioned above is characterised in CIELAB space in transmission mode of standard illuminant D65, with a 10° observer and a measurement geometry of d: 0°, by the parameters L*=66, a*=34, b*=52 and has an orange appearance.

According to another exemplary embodiment of the present invention, schematically shown in FIG. 2, the stack of thin-film dielectric coatings 110 comprises three layers, including an intermediate layer 113 made of Al₂O₃ sandwiched between the base layer 112 and the terminal layer 111, which are themselves made of TiO₂.

The base layer 112 and the terminal layer 111 have a thickness comprised between 35 nm and 55 nm, or even between 40 nm and 50 nm, the intermediate layer 113 has a thickness comprised between 50 nm and 70 nm, or even between 55 nm and 65 nm.

In this exemplary embodiment, the metallic face 101 is made of a gold alloy, for example comprising 75% by mass of gold, and 25% by mass of silver and/or of copper to arrive at 100%, for example 15% to 16% silver and 9% to 10% copper.

The metallic face 101 thus has a complex refractive index at a wavelength of 550 nm, the real part n of which is equal to 0.4 and the imaginary part k of which is equal to 2.2.

The interference colour obtained using the parameters mentioned above is characterised in CIELAB space in transmission mode of standard illuminant D65, with a 10° observer and a measurement geometry of d: 0°, by the parameters L*=76, a*=21, b*=−27 and has a pink appearance.

In other exemplary embodiments, the metallic face 101 can be made of a gold alloy comprising 75% by mass of gold, and 12% to 13% of silver and 12% to 13% of copper, the total being equal to 100%.

More generally, it should be noted that the embodiments and uses considered above have been described by way of non-limiting examples, and that other variants are therefore conceivable.

In particular, the substrate 100 is formed by a body on which a metallic layer can be deposited, for example by electrodeposition, by physical vapour deposition, known to persons skilled in the art by the acronym “PVD,” or by chemical vapour deposition, known to persons skilled in the art by the acronym “CVD.” The metallic face 101 is therefore formed by the metallic layer thus deposited. Such a metallic layer thus has a thickness comprised between 50 nm and 10 μm, and preferentially between 50 nm and 500 nm.

1. An external part for use in horology, jewellery or fine jewellery, comprising a substrate having a metallic face made of a noble metal or of a noble metal alloy in which the complex refractive index at a wavelength of 550 nm has a real part n<1 and an imaginary part 2<k<3, on which is deposited a stack of thin-film dielectric coatings, each including a thin atomic film, formed by at least one alternation of layers made of TiO₂ and Al₂O₃ and comprising a terminal layer made of TiO₂ and a base layer resting on the metallic face made of TiO₂ or of Al₂O₃.

2. The external part according to claim 1, wherein the metallic face is made of gold or platinum, or an alloy of one of these metals.

3. The external part according to claim 2, wherein the metallic face is made of a gold alloy comprising 75% by mass of gold, and 25% by mass of silver and/or of copper to arrive at 100%.

4. The external part according to claim 1, wherein the stack of thin-film dielectric coatings comprises two layers, the base layer being made of Al₂O₃.

5. The external part according to claim 4, wherein the base layer has a thickness comprised between 1 nm and 10 nm, and the terminal layer has a thickness comprised between 10 nm and 30 nm.

6. The external part according to claim 5, wherein the metallic face is made of a gold alloy comprising 75% by mass of gold, from 4.5% to 5.5% by mass of silver and from 19.5% to 20.5% by mass of copper, the total being equal to 100%.

7. The external part according to claim 1, wherein the stack of thin-film dielectric coatings comprises three layers, including an intermediate layer made of Al₂O₃ sandwiched between the base layer and the terminal layer, which are themselves made of TiO₂.

8. The external part according to claim 7, wherein the base layer and the terminal layer have a thickness comprised between 35 nm and 55 nm, and the intermediate layer has a thickness comprised between 50 nm and 70 nm.

9. The external part according to claim 1, wherein the metallic face is made of a gold alloy comprising 75% by mass of gold, 15% to 16% by mass of silver and 9% to 10% by mass of copper, the total being equal to 100%.
